(19) United States
(12) Patent Application Publication
(10) Pub. No.: US 2007/0148954 A1
(43) Pub. Date: Jun. 28, 2007

(54) Method of manufacturing semiconductor device

(75) Inventor: Choong Bae Kim, Yongin-si (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Icheon-si (KR)

(21) Appl. No.: 11/491,584

(22) Filed: Jul. 24, 2006

(30) Foreign Application Priority Data
Dec. 23, 2005 (KR) 2005-128774

(51) Int. Cl. H01L 21/4763

(52) U.S. Cl. 438/618; 257/E21.627

(57) ABSTRACT

A method of manufacturing semiconductor devices, including the steps of forming an interlayer insulating layer over a semiconductor substrate in which a predetermined structure including a drain is formed, etching a part of the interlayer insulating layer to form a contact hole, and then forming a first conductive film on the entire structure including the contact hole, blanket-etching the first conductive film so that the first conductive film remains on a surface of the contact hole, forming a second conductive film on the entire structure, burying a contact hole, and then performing a blanket-etch or CMP process using the interlayer insulating layer as a stopper, and forming a metal line layer on the entire structure.

### BACKGROUND

1. Field of the Invention

The invention relates generally to a method of manufacturing semiconductor devices. More particularly, the invention relates to a method of manufacturing a semiconductor device, wherein a contact plug is formed by filling a contact hole of a NAND flash memory with first and second conductive films, thereby preventing attack on void, which may occur when a subsequent metal line layer is formed.

2. Discussion of Related Art

As the level of integration of semiconductor devices has increased, the line width of a line per unit area is reduced and the size of a contact hole is also reduced. That is, as the size of the contact hole decreases, there has been active research into a new deposition method and a damascene method employing chemical mechanical polishing (CMP).

A method of manufacturing a semiconductor device in the related art is briefly described below.

An interlayer insulating film is formed on a semiconductor substrate in which a predetermined structure including the drain is formed. A predetermined region of the interlayer insulating layer is etched to form a contact hole through which the drain is exposed.

A conductive polysilicon layer is formed to bury the contact hole. A CMP process is then performed to form a drain contact plug. A buffer oxide film typically made of TEOS (tetraethoxysilane) is deposited on the entire structure including the drain contact plug. After an insulating layer is formed, a part of the insulating layer is stripped so that the drain contact plug is exposed, thereby forming a bit line in such a manner that the conductive layer is filled.

As described above, the drain contact plug of the NAND flash memory device connects the upper metal line layer and the active regions of the lower semiconductor substrate using polysilicon. However, as semiconductor devices have become miniaturized, the bowing of the contact profile of 70 nanometers or less becomes problematic due the influence of the profile of the drain contact. Accordingly, a problem arises because the occurrence of voids when polysilicon is deposited has increased compared with semiconductor devices of 70 nanometers or more.

When a metal line layer (i.e., in a subsequent process) is formed, a fluorine-based gas is infiltrated into the void and then reacts with polysilicon, and the void expands abruptly. Even worse, there is a phenomenon in which the contact plug itself is broken. For this reason, the contact plug is insulated from the metal line layer. This has a bad effect on the devices.

### SUMMARY OF THE INVENTION

In one embodiment, the invention provides a method of manufacturing semiconductor devices, in which a contact plug is formed by filling a contact hole of a NAND flash memory with first and second conductive films, thereby preventing attack on voids, which may occur when a subsequent metal line layer is formed.

According to an embodiment of the invention, a method of manufacturing a semiconductor device includes the steps of forming an interlayer insulating layer over a semiconductor substrate in which a predetermined structure including a drain is formed; etching a part of the interlayer insulating layer to form a contact hole, and then forming a first conductive film on the entire structure including the contact hole; blanket-etching the first conductive film so that the first conductive film remains on a surface of the contact hole; forming a second conductive film on the entire structure, burying a contact hole, and then performing a blanket-etch or CMP process using the interlayer insulating layer as a stopper; and, forming a metal line layer on the entire structure.

The first conductive film may preferably be formed of polysilicon.

The second conductive film may preferably be formed of a metal or a metal oxide, such as tungsten (W).

The method may preferably further include the step of after the first conductive film is formed, forming an adhesive layer preferably using titanium (Ti/TiN) before the second conductive film is formed.

### BRIEF DESCRIPTION OF THE DRAWINGS

A more compete appreciation of the invention, and many of the attendant advantages thereof, will be readily apparent as the same becomes better understood by reference to the following detailed description when considered in conjunction with the accompanying drawings in which like reference symbols indicate the same or similar components, wherein:

FIG. 1 is a plan view illustrating a part of a cell array region of a flash memory device to which the invention is applied; and

FIGS. 2A to 2C cross-sectional views illustrating a method of manufacturing the semiconductor device take along line A-A in FIG. 1 according to an embodiment of the invention.

### DETAILED DESCRIPTION OF EMBODIMENTS

The invention will be described in detail in connection with certain exemplary embodiments with reference to the accompanying drawings.

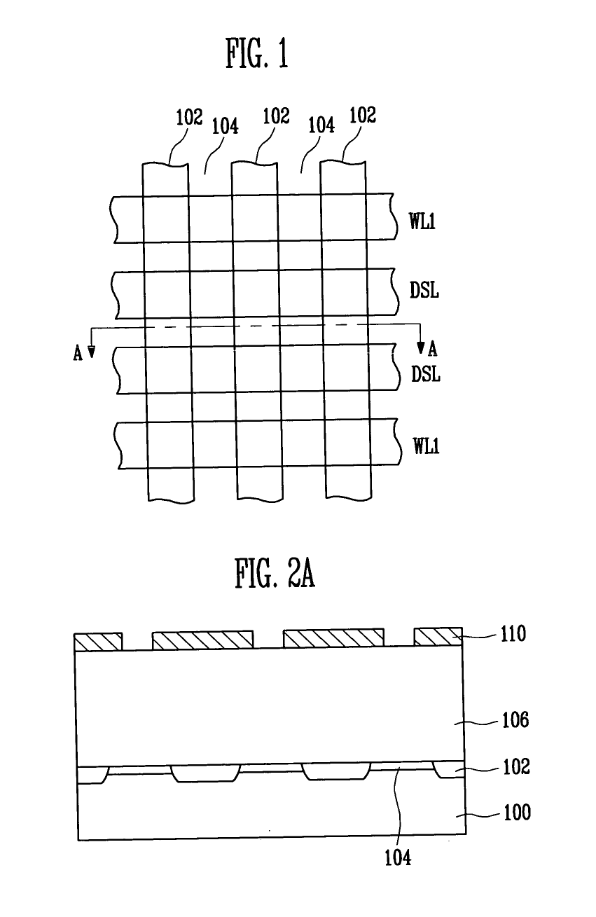

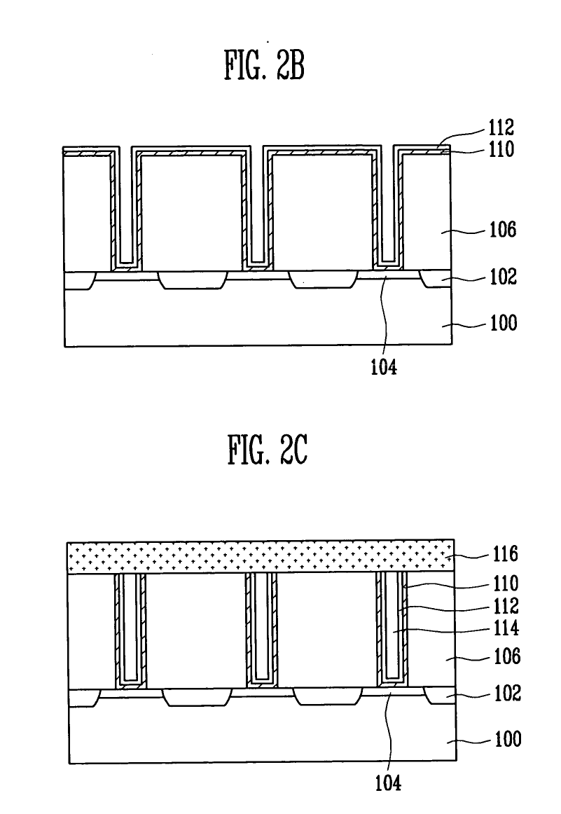

FIG. 1 is a plan view illustrating a part of a cell array region of a flash memory device to which the invention is applied. FIGS. 2A to 2C cross-sectional views illustrating a method of manufacturing the semiconductor device take along line A-A in FIG. 1 according to an embodiment of the invention.

In other words, it may be considered that the invention is applied to the whole region in which a contact can be formed in a semiconductor device. However, FIGS. 2A to 2C illustrate processes of forming a drain contact plug in a region between drain select lines (DSL).

Referring to FIGS. 1 and 2A, a first interlayer insulating layer 106 is formed over a semiconductor substrate 100 in which an isolation film 102 and active regions 104 are defined.

The active region 104 refers to the drain. The interlayer insulating layer 106 may be formed to a thickness of 5000 Å to 20000 Å using a material such as boron phosphorous silicate glass (BPSG), phosphorous silicate glass (PSG), fluorinated silicate glass (FSG), plasma enhanced-tetra ethylene ortho silicate (PE-TEOS), plasma enhanced-SiH₄ (PE-SiH₄), high density plasma undoped silicate glass (HDP USG), or advanced planarization layer (APL). Furthermore, the interlayer insulating layer 106 may be formed using one material or may have a lamination structure two or more materials including a nitride film, etc. are laminated.

A photoresist pattern (not shown) is formed on the interlayer insulating layer 106.

Referring to FIG. 2B, a part of the interlayer insulating layer 106 is etched preferably by photo and etch processes using the photoresist pattern (not shown) as a mask, thereby forming a contact hole through the active regions 104 of the semiconductor substrate are exposed. A first conductive film 110 is then formed on the entire structure 10. The first conductive film 110 may be formed using polysilicon, for example.

Thereafter, a blanket etch process is performed so that the first conductive film 110 remains on the surface of the contact hole and a top surface of the interlayer insulating layer 106. In this case, the first conductive film 110 may be formed only on the surface of the contact hole and the top surface of the interlayer insulating layer 106 in the formation process of the first conductive film 110 so that the blanket etch process may not be performed.

A thin adhesive layer 112 preferably made of titanium (Ti/TiN) is formed on the entire structure.

Referring to FIG. 2C, a second conductive film 114 is formed on the entire structure including the adhesive layer 112 so that the contact hole is completely buried, thereby forming a contact plug. The second conductive film 114 may be formed using metal and/or metal oxide, preferably containing tungsten (W).

After CMP or an etch process is performed, a metal line layer 116 is formed on the entire structure. When the CMP process or the etch process is performed, a partial CMP process or a partial etch process may be performed rather than a blanket CMP process or a blanket etch process through which up to the interlayer insulating layer 106 is lost. Thereafter, the remnants are etched in the etch process of a subsequent metal line layer 116, thereby completing insulation.

Meanwhile, after the second conductive film 114 is deposited in the contact hole, the contact plug and the metal line layer 116 may be formed at the same time using a mask process for a metal line and etching without the need to perform the CMP process or the etch process.

As described above, according to the invention, the contact hole of the NAND flash memory is buried with the first and second conductive films in order to form the contact plug. Accordingly, attack on void, which may occur when a subsequent metal line layer is formed, can be prevented.

While the invention has been described in connection with practical exemplary embodiments, the invention is not limited to the disclosed embodiments but, to the contrary, is intended to cover various modifications and equivalent arrangements included within the spirit and scope of the appended claims.

What is claimed is:

1. A method of manufacturing a semiconductor device, the method comprising the steps of:
forming an interlayer insulating layer over a semiconductor substrate in which a predetermined structure including a drain is formed;
etching a part of the interlayer insulating layer to form a contact hole, and then forming a first conductive film on the entire structure including the contact hole;
blanket-etching the first conductive film so that the first conductive film remains on a surface of the contact hole;
forming a second conductive film on the entire structure, burying a contact hole, and then performing a blanket-etch or chemical mechanical polishing process using the interlayer insulating layer as a stopper; and
forming a metal line layer on the entire structure.

2. The method of claim 1, wherein the first conductive film is formed of polysilicon.

3. The method of claim 1, wherein the second conductive film is formed of a metal and/or a metal oxide.

4. The method of claim 1, wherein the second conductive film comprises tungsten (W).

5. The method of claim 1, further comprising the step of after the first conductive film is formed, forming an adhesive layer using titanium (Ti/TiN) before the second conductive film is formed.
